(19) United States
(12) Patent Application Publication
(10) Pub. No.: US 2021/0384373 A1
(43) Pub. Date: Dec. 9, 2021

(54) FRONT ELECTRODE LAYER OF THIN FILM SOLAR CELL

(71) Applicant: GIANTPLUS TECHNOLOGY CO., LTD, Miaoli County (TW)

(72) Inventors: Chen-Hsi Kang, Taoyuan City (TW); Kai-Ju Chou, Taoyuan City (TW); Jian-Liang Liao, Taoyuan City (TW); Kang-Chih Liu, Taoyuan City (TW)

(73) Assignee: GIANTPLUS TECHNOLOGY CO., LTD, Miaoli County (TW)

(21) Appl. No.: 17/387,903

(22) Filed: Jul. 28, 2021

Related U.S. Application Data
(62) Division of application No. 16/919,122, filed on Jul. 2, 2020.

(30) Foreign Application Priority Data
Jun. 3, 2020 (TW) 109118618

(51) Int. Cl. H01L 31/18; C09K 13/00

(52) U.S. Cl. CPC H01L 31/1888; C09K 13/00

(57) ABSTRACT

A front electrode layer of a thin film solar cell is provided. The front electrode layer includes a first transparent conductive layer and a second transparent conductive layer. The first transparent conductive layer is disposed on a substrate, and the second transparent conductive layer is disposed on the first transparent conductive layer, wherein the first transparent conductive layer is located between the substrate and the second transparent conductive layer, and wherein a surface roughness of the second transparent conductive layer is lower than a surface roughness of the first transparent conductive layer.

### CROSS-REFERENCE TO RELATED APPLICATION

This application is a divisional application of U.S. application Ser. No. 16/919,122, filed on Jul. 2, 2020, now pending, which claims the priority benefit of Taiwan application serial no. 109118618, filed on Jun. 3, 2020. The entirety of each of the above-mentioned patent applications is hereby incorporated by reference herein and made a part of this specification.

### BACKGROUND

### Technical Field

The disclosure is related to a solar cell and a manufacturing method thereof, and particularly to a front electrode layer of a thin film solar cell and a manufacturing method thereof.

### Description of Related Art

The thin film solar cell could be classified into a thin film solar cell with a superstrate configuration and a thin film solar cell with a substrate configuration according to an incidence direction of an ambient light. With regard to the thin film solar cell with the superstrate configuration, a portion of the ambient light would penetrate a transparent substrate and then being absorbed by a photoelectric conversion layer, while the remained portion of the ambient light passed through the photoelectric conversion layer would be reflected by a back electrode layer and then being absorbed by the photoelectric conversion layer. The amount of the ambient light reflected by the back electrode layer would influence the energy conversion efficiency of the thin film solar cell. In general, an etching process would be involved in a process for manufacturing a front electrode layer so as to make the formed front electrode layer have a plurality of microstructures, thereby improving the amount of the reflected ambient light. The ambient light reaching the front electrode layer would be scattered due to the plurality of microstructures, thus, the traveling distance of the scattered light to the back electrode layer would be increased to achieve the condition of total internal reflection, thereby improving the amount of the reflected ambient light.

A stripping agent or an oxalic acid is usually used as an etching agent in the above etching process. In the event that the stripping agent is used as the etching agent to etch the front electrode layer, the etching rate is lower, which makes the formed front electrode layer have low haze value (about 8%) due to the surface thereof with slight roughness, thereby resulting in the low availability of light. In the event that the oxalic acid is used as the etching agent to etch the front electrode layer, the etching rate is higher, which makes the formed front electrode layer have high haze value (20%˜48%). However, the yield rate of the following formed film layers would be decreased (for example, the crack would occur on the surface of the front electrode layer) due to the surface of the front electrode layer with high roughness, so that the thin film solar cell including the above front electrode layer would have reduced photoelectric conversion efficiency.

### SUMMARY

An embodiment of the disclosure provides a manufacturing method of a front electrode layer of a thin film solar, wherein the formed front electrode layer has high haze value, and the following film layers formed on which has the improved yield rate.

The manufacturing method of the front electrode layer of the thin film solar cell according to an embodiment of the disclosure includes steps below. First, forming a first transparent conductive layer with a plurality of microstructures on a substrate. After that, forming a second transparent conductive layer on a surface having the plurality of microstructures of the first transparent conductive layer.

In one embodiment of the disclosure, a surface roughness of the second transparent conductive layer is lower than a surface roughness of the first transparent conductive layer.

In one embodiment of the disclosure, forming the first transparent conductive layer with the plurality of microstructures on the substrate includes steps below. First, forming a first transparent conductive material layer on the substrate. After that, progressing an etching process on the first transparent conductive material layer.

In one embodiment of the disclosure, the etching process includes a wet etching process.

In one embodiment of the disclosure, an etching agent used in the wet etching process includes an oxalic acid.

In one embodiment of the disclosure, a method for forming the first transparent conductive material layer includes a physical vapor deposition or a metal chemical vapor deposition.

In one embodiment of the disclosure, a method for forming the second transparent conductive layer includes a physical vapor deposition or a metal chemical vapor deposition.

An embodiment of the disclosure provides a front electrode layer of a thin film solar cell, wherein the front electrode layer has high haze value, and the following film layers disposed on which has the improved yield rate.

The front electrode layer of the thin film solar cell according to an embodiment of the disclosure is fabricated by progressing the above manufacturing method of the front electrode layer of the thin film solar cell, wherein a surface roughness of the second transparent conductive layer is lower than a surface roughness of the first transparent conductive layer.

Based on the above, the front electrode layer formed by progressing the manufacturing method of the thin film solar cell according to an embodiment of the disclosure includes the first transparent conductive layer and the second transparent conductive layer disposed thereon, wherein the first transparent conductive layer is formed by progressing the etching process so as to have the plurality of microstructures and high surface roughness. As a result, the front electrode layer could have high haze value while the ambient light passes through the substrate and then irradiates to the first transparent conductive layer. Furthermore, the second transparent conductive layer has lower surface roughness compared to the first transparent conductive layer, which could be used to compensate for the high surface roughness of the first transparent conductive layer, so that the yield rate of the following film layers formed on the second transparent conductive layer would not be decreased (for example, the crack would not occur on the surface of the second transparent conductive layer) since the high surface roughness of the first transparent conductive layer is compensated, thereby preventing the photoelectric conversion efficiency of the thin film solar cell from being reduced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a flow diagram of the manufacturing method of the thin film solar cell according to one embodiment of the disclosure.

FIG. 2 is a schematic cross-sectional view of the parts of the thin film solar cell according to one embodiment of the disclosure.

### DESCRIPTION OF THE EMBODIMENTS

The disclosure is more comprehensively described with reference to the figures of the present embodiments. However, the disclosure may also be implemented in various different forms, and is not limited to the embodiments in the present specification. The thicknesses of the layers and regions in the figures are enlarged for clarity. The same or similar reference numerals represent the same or similar devices and are not repeated in the following paragraphs. Additionally, directional terminology, such as “top,” “bottom,” “left,” “right,” “front,” or “back,” etc., is used with reference to the orientation of the Figure(s) being described. As such, the directional terminology is used for purposes of illustration and is in no way limiting.

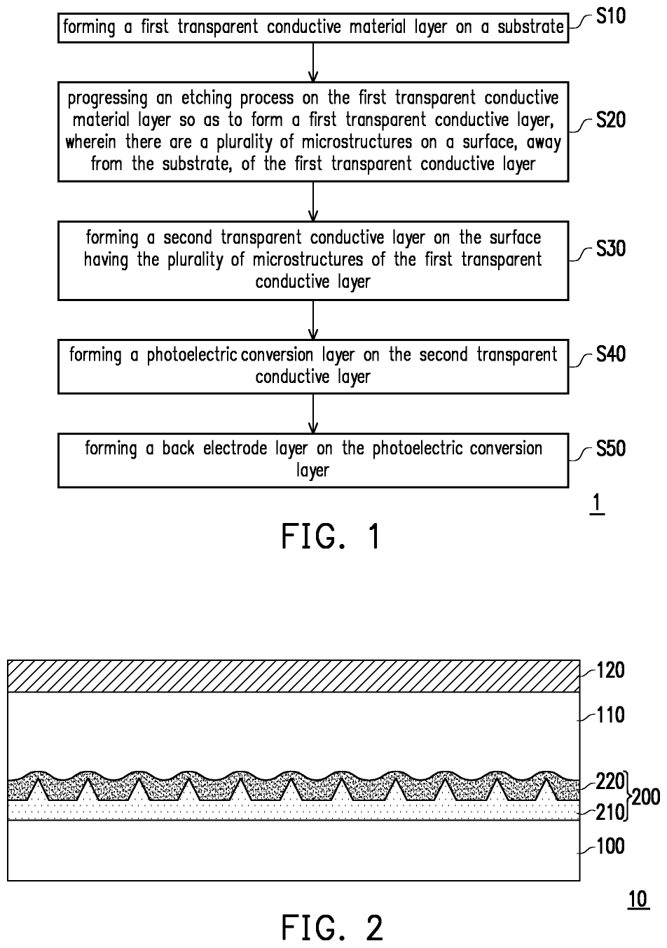

FIG. 1 is a flow diagram of the manufacturing method 1 of the thin film solar cell according to one embodiment of the disclosure.

Referring to FIG. 1, in step S10, forming a first transparent conductive material layer on a substrate. The substrate is, for example, formed with a transparent material so as to make an ambient light penetrate which and get inside the thin film solar cell. In some embodiments, a material of the substrate includes glass, transparent resin or other suitable transparent material. The above transparent resin may be, for example, polyethylene terephthalate, polyethylene naphthalate, polycarbonate, polyether or polyimide. In the present embodiment, the material of the substrate is glass. A forming method of the first transparent conductive material layer is performed, for example, by using a physical vapor deposition or a metal chemical vapor deposition to form the first transparent conductive material layer on the overall substrate. In some embodiments, a material of the first transparent conductive material layer includes a transparent conductive oxide (TCO). For example, the material of the first transparent conductive material layer may include indium tin oxide (ITO), aluminum doped zinc oxide (AZO), stannic oxide (SnO₂), or indium oxide (In₂O₃).

In step S20, progressing an etching process on the first transparent conductive material layer so as to form a first transparent conductive layer, wherein there are a plurality of microstructures on a surface, away from the substrate, of the first transparent conductive layer. The purpose of progressing the etching process is to form the surface, away from the substrate, of the first transparent conductive material layer with the improved surface roughness by removing a portion of the first transparent conductive material layer. In some embodiments, the above etching process includes a wet etching process, a dry etching process, or a combination thereof. The wet etching process is adopted in the present embodiment. In the present embodiment, an oxalic acid is used as an etching agent in the wet etching process since the etching rate is higher while being used to etch the first transparent conductive material layer, thereby tending to make the surface, away from the substrate, of the first transparent conductive material layer have higher surface roughness, but the disclosure is not limited thereto. Namely, other etching agent having high etching rate relative to the material of the first transparent conductive material layer could be chosen.

In step S30, forming a second transparent conductive layer on the surface having the plurality of microstructures of the first transparent conductive layer. A forming method of the second transparent conductive layer is performed, for example, by using a physical vapor deposition or a metal chemical vapor deposition to form the second transparent conductive layer on the overall surface having the plurality of microstructures of the first transparent conductive layer. A surface roughness of the second transparent conductive layer is lower than the surface roughness of the first transparent conductive layer since the second transparent conductive layer is formed by progressing the film deposition. In some embodiments, a material of the second transparent conductive layer includes a transparent conductive oxide. For example, the material of the second transparent conductive layer may include indium tin oxide, aluminum doped zinc oxide, stannic oxide, or indium oxide.

So far a fabrication of a front electrode layer of the thin film solar cell is accomplished. In detail, the front electrode layer of the thin film solar cell according to the disclosure includes the first transparent conductive layer and the second transparent conductive layer disposed thereon. An ambient light passing through the substrate and then irradiating to the front electrode layer could be scattered well since the first transparent conductive layer is formed by progressing the above etching process so as to have higher surface roughness. Namely, the first transparent conductive layer of the front electrode layer could have higher haze value, thereby improving the availability of the ambient light. Furthermore, the second transparent conductive layer disposed on the front electrode layer is formed by progressing the film deposition, which could be used to compensate for the high surface roughness of the first transparent conductive layer, so that the yield rate of the following film layers formed on the second transparent conductive layer would not be decreased (for example, the crack would not occur on the surface of the second transparent conductive layer) since the high surface roughness of the first transparent conductive layer is compensated, thereby preventing the photoelectric conversion efficiency of the thin film solar cell from being reduced.

In step S40, forming a photoelectric conversion layer on the second transparent conductive layer. A forming method of the photoelectric conversion layer is performed, for example, by using a chemical vapor deposition, but the disclosure is not limited thereto. In some embodiments, a material of the photoelectric conversion layer may include single crystalline silicon, polycrystalline silicon, or amorphous silicon. Namely, the thin film solar cell according to the present embodiment may be a kind of a thin film silicon solar cell. In the present embodiment, the material of the photoelectric conversion layer is amorphous silicon. The photoelectric conversion layer includes, for example, a first extrinsic semiconductor layer, an intrinsic semiconductor layer and a second extrinsic semiconductor layer laminated thereon in this order, wherein the first extrinsic semiconductor layer includes a first doping type, and the second extrinsic semiconductor layer includes a second doping type. The above first doping type and second doping type respectively are one of P-type and N-type. In the present embodiment, the first doping type is P-type, and the second doping type is N-type, but the disclosure is not limited thereto.

In step S50, forming a back electrode layer on the photoelectric conversion layer. A forming method of the back electrode layer is performed, for example, by using a sputter deposition or a chemical vapor deposition, but the disclosure is not limited thereto. A material of the back electrode layer is, for example, metal, alloy, or metal oxide. For example, the material of the back electrode layer includes molybdenum-tantalum, or a combination of molybdenum-tantalum and aluminum.

So far a fabrication of the thin film solar cell is accomplished.

The fabrication of the thin film solar cell of the present embodiment is explained as an example by the above method, but the forming method of the thin film solar cell according to the disclosure is not limited thereto.

Referring to FIG. 2, FIG. 2 is a schematic cross-sectional view of the parts of the thin film solar cell 10 according to one embodiment of the disclosure. The thin film solar cell 10 according to the embodiment of the present disclosure includes a substrate 100, a front electrode layer 200, a photoelectric conversion layer 110 and a back electrode layer 120, wherein the front electrode layer 200 includes a first transparent conductive layer 210 and a second transparent conductive layer 220. For the materials and effects of the substrate 100, the front electrode layer 200, the photoelectric conversion layer 110 and the back electrode layer 120, reference is made to the foregoing embodiments, and the descriptions thereof are omitted in the present embodiment. In some embodiments, a thickness of the first transparent conductive layer 210 is about 0.5 μm˜1.0 μm, a thickness of the second transparent conductive layer 220 is about 0.5 μm˜1.0 μm, and a gross thickness of the first transparent conductive layer 210 and the second transparent conductive layer 220 is 1.0 μm˜1.5 μm. In some embodiments, the ratio of the thickness of the first transparent conductive layer 210 to the thickness of the second transparent conductive layer 220 is 1:2˜2:1. In the present embodiment, the ratio of the thickness of the first transparent conductive layer 210 to the thickness of the second transparent conductive layer 220 is 1:1, but the disclosure is not limited thereto. It is worth mentioned that the forming process of the first transparent conductive layer 210 would undergo the etching process, which makes its thickness reduced. Therefore, the thickness of the first transparent conductive layer 210 could be smaller than the thickness of the second transparent conductive layer 220 in other embodiments. Furthermore, a thickness of the front electrode layer 200 including the first transparent conductive layer 210 according to the present embodiment is slightly smaller than a thickness of the front electrode layer of the traditional thin film solar cell. Moreover, the front electrode layer 200 according to the present embodiment has a haze value of 16%˜35%.

### EXPERIMENTAL EXAMPLE

The present disclosure would be further explained below by an example and a plurality of comparative examples, but the examples is a use of exemplary embodiments and is not a use of limitation of the scope of the present disclosure.

There are variable structures of the front electrode layer applied to the thin film solar cell in Example 1, Comparative Example 1 and Comparative Example 2, respectively.

The thin film solar cell 10 of the present embodiment is used as Example 1, wherein the front electrode layer 200 of the thin film solar cell 10 includes the first transparent conductive layer 210 and the second transparent conductive layer 220. The first transparent conductive layer 210 having a plurality of microstructures is formed by first progressing the film deposition and then progressing the etching process by using the oxalic acid as the etching agent. The second transparent conductive layer 220 is formed by progressing the film deposition.

The front electrode layer having a plurality of microstructures of the thin film solar cell is formed by first progressing the film deposition and then progressing the etching process by using the stripping agent as the etching agent, which is included in the thin film solar cell in Comparative Example 1.

The front electrode layer having a plurality of microstructures of the thin film solar cell is formed by first progressing the film deposition and then progressing the etching process by using the oxalic acid as the etching agent, which is included in the thin film solar cell in Comparative Example 2.

The experimental data of Example 1, Comparative Example 1 and Comparative Example 2 are collected in Table 1 below.

TABLE 1

| | The haze | The photoelectric | The fill |
|---|---|---|---|
| | value of the | conversion efficiency | factor of the |
| | front electrode | of the thin film | thin film solar |
| | layer (%) | solar cell (%) | cell (%) |
| Example 1 | 25% | 6.6% | 65% |
| Comparative | 8% | 6% | 60% |
| Example 1 | | | |
| Comparative | 40% | 5.1% | 54% |
| Example 2 | | | |

It could be seen in Table 1 that the etching rate is relatively low in the thin film solar cell of Comparative Example 1 since the stripping agent is used as the etching agent to etch the front electrode layer, which makes the front electrode layer have smaller roughness. In addition, the thin film solar cell of Comparative Example 1 has lower haze value compared to the thin film solar cell 10 of Example 1. In contrast, the first transparent conductive layer 210 of thin film solar cell of Example 1 has higher roughness compared to the front electrode layer of Comparative Example 1, and the front electrode layer 200 including the first transparent conductive layer 210 has higher haze value, thereby improving the luminous flux entering the photoelectric conversion layer 110 and resulting in the high availability of ambient light.

Furthermore, it could be seen in Table 1 that the front electrode layer in the thin film solar cell of Comparative Example 2 has high haze value since the oxalic acid is used as the etching agent to etch the front electrode layer. However, the yield rate of the following formed photoelectric conversion layer would be decreased due to the surface of the front electrode layer with high roughness, so that the thin film solar cell of Comparative Example 2 would have relatively low photoelectric conversion efficiency and fill factor (which is proportional to photoelectric conversion efficiency). In contrast, the second transparent conductive layer 220 included in the front electrode layer 200 of the thin film solar cell 10 could be used to compensate for the high surface roughness of the first transparent conductive layer 210, so that the yield rate of the photoelectric conversion layer 110 formed on the second transparent conductive layer 220 would not be decreased (for example, the crack would not occur on the surface of the second transparent conductive layer 220) since the high surface roughness of the first transparent conductive layer 210 is compensated. Based on the above, the thin film solar cell 10 of Example 1 has better photoelectric conversion efficiency and fill factor by combining the high haze value of the front electrode layer 200.

In summary, the front electrode layer formed by progressing the manufacturing method of the thin film solar cell according to the present disclosure includes the first transparent conductive layer and the second transparent conductive layer disposed thereon, wherein the first transparent conductive layer is formed by progressing the etching process so as to have the plurality of microstructures and high surface roughness. As a result, the ambient light passing through the substrate and then irradiating to the front electrode layer could be scattered well, thereby improving the luminous flux entering the photoelectric conversion layer and resulting in the high availability of the ambient light. Furthermore, the second transparent conductive layer is formed by progressing the film deposition, which could be used to compensate for the high surface roughness of the first transparent conductive layer, so that the yield rate of the following photoelectric conversion layer formed on the second transparent conductive layer would not be decreased (for example, the crack would not occur on the surface of the second transparent conductive layer), thereby making the thin film solar cell have better photoelectric conversion efficiency and fill factor.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A front electrode layer of a thin film solar cell, including:
a first transparent conductive layer, disposed on a substrate; and
a second transparent conductive layer, disposed on the first transparent conductive layer,
wherein the first transparent conductive layer is located between the substrate and the second transparent conductive layer,
wherein a surface roughness of the second transparent conductive layer is lower than a surface roughness of the first transparent conductive layer.

2. The front electrode layer of the thin film solar cell according to claim 1, wherein a ratio of a thickness of the first transparent conductive layer to a thickness of the second transparent conductive layer is 1:2˜2:1.

3. The front electrode layer of the thin film solar cell according to claim 2, wherein the ratio of the thickness of the first transparent conductive layer to the thickness of the second transparent conductive layer is 1:1.

4. The front electrode layer of the thin film solar cell according to claim 1, wherein a thickness of the first transparent conductive layer is 0.5 μm˜1.0 μm, and a thickness of the second transparent conductive layer is 0.5 μm˜1.0 μm.

5. The front electrode layer of the thin film solar cell according to claim 1, wherein a gross thickness of the first transparent conductive layer and the second transparent conductive layer is 1.0 μm˜1.5 μm.

6. The front electrode layer of the thin film solar cell according to claim 1, wherein a thickness of the first transparent conductive layer is smaller than a thickness of the second transparent conductive layer.

7. The front electrode layer of the thin film solar cell according to claim 1, wherein a material of the first transparent conductive layer and a material of the second transparent conductive layer include indium tin oxide, aluminum doped zinc oxide, stannic oxide, or indium oxide.

8. The front electrode layer of the thin film solar cell according to claim 1, wherein the front electrode layer has a haze value of 16%˜35%.
